(19) United States
(12) Patent Application Publication
(10) Pub. No.: US 2007/0258796 A1
(43) Pub. Date: Nov. 8, 2007

(54) METHODS AND APPARATUS FOR TRANSPORTING SUBSTRATE CARRIERS

(76) Inventors: Eric Andrew Englhardt, Palo Alto, CA (US); Sushant S. Koshti, Sunnyvale, CA (US)

Correspondence Address: DUGAN & DUGAN, PC, 55 SOUTH BROADWAY, TARRYTOWN, NY, 10591, US

(21) Appl. No.: 11/740,914

(22) Filed: Apr. 26, 2007

Related U.S. Application Data
(60) Provisional application No. 60/795,481, filed on Apr. 26, 2006.

(51) Int. Cl. H01L 21/677

(52) U.S. Cl. 414/217

(57) ABSTRACT

In some aspects, an inter-building substrate carrier transport system is provided that includes (1) a housing that extends outside of and between a first building and a second building; (2) a conveyor positioned within the housing and adapted to (a) receive a substrate carrier at the first building; and (b) transport the substrate carrier to the second building within the housing; and (3) an environmental control system adapted to at least one of monitor and control an environment within the housing so as to protect the substrate carrier from an environment outside of the housing. Numerous other aspects are provided.

The present application claims priority from U.S. Provisional Patent Application Ser. No. 60/795,481, filed Apr. 26, 2006, which is hereby incorporated by reference herein in its entirety.

### FIELD OF THE INVENTION

The present invention relates to electronic device manufacturing, and more particularly to methods and apparatus for transporting substrate carriers.

### BACKGROUND

Manufacturing of semiconductor devices typically involves performing a sequence of procedures with respect to a substrate such as a silicon substrate, a glass plate, etc. (Such substrates may also be referred to as wafers, whether patterned or unpatterned.) These steps may include polishing, deposition, etching, photolithography, heat treatment, and so forth. Usually a number of different processing steps may be performed in a single processing system or “tool” which includes a plurality of processing chambers. However, it is generally the case that other processes are required to be performed at other processing locations within a fabrication facility, and it is accordingly necessary that substrates be transported within the fabrication facility from one processing location to another. Depending upon the type of semiconductor device to be manufactured, there may be a relatively large number of processing steps required to be performed at many different processing locations within the fabrication facility.

It is conventional to transport substrates from one processing location to another within substrate carriers such as sealed pods, cassettes, containers and so forth. It is also conventional to employ automated substrate carrier transport devices, such as automatic guided vehicles, overhead transport systems, substrate carrier handling robots, etc., to move substrate carriers from location to location within the fabrication facility or to transfer substrate carriers from or to a substrate carrier transport device.

For an individual substrate, the total fabrication process, from formation or receipt of the virgin substrate to cutting of semiconductor devices from the finished substrate, may require an elapsed time that is measured in weeks or months. In a typical fabrication facility, a large number of substrates may accordingly be present at any given time as “work in progress” (WIP). The substrates present in the fabrication facility as WIP may represent a very large investment of working capital, which tends to increase the per substrate manufacturing cost. It would therefore be desirable to reduce the amount of WIP for a given substrate throughput for the fabrication facility. To do so, the total elapsed time for processing each substrate should be reduced.

### SUMMARY

In some aspects, an inter-building transport system is provided that includes (1) a housing that extends outside of and between a first building and a second building; (2) a conveyor positioned within the housing and adapted to (a) receive a substrate carrier at the first building; and (b) transport the substrate carrier to the second building within the housing; and (3) an environmental control system adapted to at least one of monitor and control an environment within the housing so as to protect the substrate carrier from an environment outside of the housing.

In certain aspects, a method is provided for transporting substrate carriers that includes (1) unloading a substrate carrier from a first building; (2) loading the substrate carrier onto a conveyor within a controlled environment housing that extends between the first building and a second building; (3) transporting the substrate carrier to the second building through the housing the conveyor; and (4) unloading the substrate carrier from the conveyor to the second building.

In some aspects, an inter-building transport system is provided that includes (1) a housing that extends outside of and between a first building and a second building; and (2) a conveyor positioned within the housing and adapted to (a) receive a substrate carrier at the first building; and (b) transport the substrate carrier to the second building within the housing. The conveyor is adapted to receive substrate carriers from the first building at a first elevation and deliver substrate carriers to the second building at a second elevation.

In certain aspects, a method is provided for transporting substrate carriers that includes (1) unloading a substrate carrier from a first building; (2) loading the substrate carrier onto a conveyor within a housing that extends between the first building and a second building; (3) transporting the substrate carrier to the second building through the housing the conveyor; and (4) unloading the substrate carrier from the conveyor to the second building. Transporting the substrate carrier includes changing an elevation of the substrate carrier. Numerous other aspects are provided.

Other features and aspects of the present invention will become more fully apparent from the following detailed description, the appended claims and the accompanying drawings.

### BRIEF DESCRIPTION OF THE DRAWINGS

FIG. 1 is a schematic representation of a top view of an example embodiment of an inter-building transport system according to some aspects of the present invention.

FIG. 2 is a schematic representation of an elevational view of an example embodiment of an inter-building transport system according to some aspects of the present invention.

FIG. 3 is a schematic representation of an elevational view of an alternative example embodiment of an inter-building transport system according to some aspects of the present invention.

FIG. 4 is a schematic representation of an elevational view of an additional alternative example embodiment of an inter-building transport system according to some aspects of the present invention.

FIG. 5 is a cross-sectional perspective view of an example embodiment of a segment of an inter-building transport system according to some aspects of the present invention.

FIG. 6 is a plan view of a conveyor supporting an example embodiment of a substrate carrier batch carrier for use with an inter-building transport system according to some aspects of the present invention.

FIG. 7 is a flowchart depicting an example embodiment of a method of using an inter-building transport system according to some aspects of the present invention.

### DETAILED DESCRIPTION

The present invention provides a cost efficient means to expand an existing electronic device manufacturing fabrication facility (hereinafter “Fab”) into buildings relatively near to the Fab. In some embodiments, the present invention may be used to construct a Fab in two or more existing buildings that individually may not be large enough to house a Fab. In additional or alternative embodiments, the present invention may be used to efficiently store or warehouse work-in-progress, manufacturing materials, and/or finished goods in a building separate from a Fab. Through the use of environmentally controlled housings or enclosures that are adapted to extend between two or more buildings, conveyors (e.g., high speed, continuous motion conveyors) may be adapted to span from one building to another, protected by the housing. In some embodiments, an inter-building transport system according to the present invention may link, for example, a plurality of high-speed overhead transport systems so that, under the control of a Fab's manufacturing execution system (and/or a material control system), substrate carriers may be transported directly between tool stations, storage areas, etc. in different buildings.

In some embodiments, the inter-building transport system may be adapted to facilitate changing the elevation of the transported substrate carriers such that, for example, two different overhead transport systems in two different buildings at two different elevations may be linked by the inter-building transport system. In such embodiments, the inter-building transport system may be inclined, include one or more vertical elevator portions, and/or may spiral upward (or downward) to adapt to the elevation difference between the two different overhead transport systems.

In some embodiments the inter-building transport system of the present invention may be adapted to move individual substrate carriers individually, as batches of independent substrate carriers queued up, for example, at a tool station, and/or in a substrate carrier batch carrier. A substrate carrier batch carrier may be adapted to hold a plurality of substrate carriers. The present invention may be particularly useful for transporting small lot substrate carriers which are adapted to hold fewer substrates than conventional large lot carriers which may typically be adapted to hold 13 or 25 or more substrates. In some embodiments, the substrate carriers may be adapted to couple to each other such that a plurality of coupled substrate carriers may be moved together as a batch. In all cases, the inter-building transport system of the present invention may be adapted to meet the throughput capacity of the transport systems which the inter-building transport system serves.

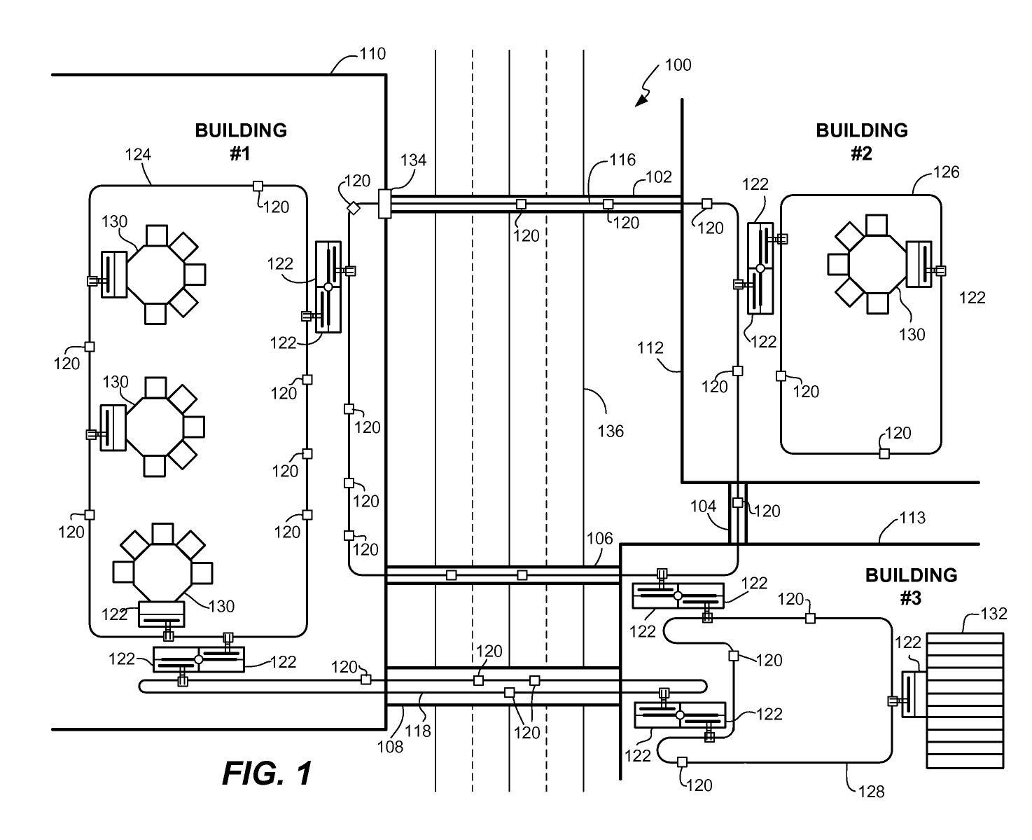

Turning to FIG. 1, a schematic representation depicting a top view of an example inter-building transport system 100 according to some aspects of the present invention is provided. An inter-building transport system 100 may include one or more housings 102, 104, 106, 108, that are each adapted to span between two or more buildings 110, 112, 114. Within the housings 102, 104, 106, 108, inter-building conveyors 116, 118 may transport substrate carriers 120 between the buildings 110, 112, 114. The inter-building conveyors 116, 118 may receive substrate carriers 120 at stockers 122 that are adapted to load and unload substrate carriers 120 from internal conveyors 124, 126, 128 that are each located entirely within different buildings 110, 112, 114. The stockers 122 may also be adapted to transfer, load and unload substrate carriers 120 from/to other co-located stockers 122, processing tools 130, and storage systems 132. In some embodiments, the inter-building transport system 100 may include a cleaning station 134 adapted to clean particles and any potential contaminants from substrate carriers 120 that pass through the housings 102. The cleaning station 134 may include vacuum channels, air curtains, mechanical brushes and/or wipers. Alternatively or additionally, the environment of the building 110, 112, 114 (e.g., a clean room environment) may be maintained within the housings 102, 104, 106, 108.

In some embodiments, one or more of the housings 102, 104, 106, 108 of the inter-building transport system 100 may be disposed below ground level in subterranean tunnels or underpasses. In some embodiments, one or more of the housings 102, 104, 106, 108 may be disposed at or above ground level. For example, a housing segment may span from the eighth floor of Building #1 110, across a roadway 136, to the 5^{th} floor of Building #2 112.

In some embodiments, a housing 108 may be adapted to enclose a two-way inter-building conveyor 118, and in other embodiments, the housing 102 may be adapted to enclose a one-way inter-building conveyor 116. In a two-way inter-building conveyor 118, the substrate carriers 120 may be transported side-by-side (e.g., at the same elevation) as depicted in FIG. 1, 118, or the substrate carriers 120 may be transported above-and-below each other as will be described in more detail below.

In some embodiments, the housings 102, 104, 106, 108 may include, or be attached to, structural elements (not shown) adapted to support the housings 102, 104, 106, 108 when configured to bridge between buildings 110, 112, 114. Alternatively, the housings 102, 104, 106, 108 may be constructed to be self-supporting and/or free-standing.

In various embodiments, individual substrate carriers 120 may be moved on the inter-building conveyors 116, 118 at evenly spaced intervals, at randomly spaced intervals, and/or grouped in batches. In some embodiments, the stockers 122 may be adapted to queue up two or more substrate carriers 120 into a batch and load the entire batch onto the inter-building conveyors 116, 118 in a single loading action. In some embodiments, as will be discussed in more detail below, a batch carrier may be used to support a batch of substrate carriers on the inter-building conveyors 116, 118.

In some embodiments, the inter-building conveyors 116, 118 may be the same type of conveyers (e.g., a high speed, continuously moving, overhead transport system as described in U.S. patent application Ser. No. 10/650,480 which is hereby incorporated by reference herein in its entirety) used for the internal conveyors 124, 126, 128. In other embodiments, the inter-building conveyors 116, 118 and the internal conveyors 124, 126, 128 may be different. For example, the internal conveyors 124, 126, 128 may be high speed, continuously moving, overhead transport systems and the inter-building conveyors 116, 118 may be embodied as autonomous robotic vehicles adapted to carry substrate carriers 120 along a track. In some embodiments, “trains” of cars or vehicles, e.g., with a lead driving vehicle, may be employed to move batches of substrate carriers 120. The trains may move continuously and be loaded and unloaded using speed matching between the stockers 122 and the train cars. In some embodiments there may be at least as many vehicles in each train as there are substrate carrier entry-points and exit-points in each building.

In some embodiments, instead of co-located stockers 122, alternative conveyor-to-conveyor transfer mechanisms may be used to transfer substrate carriers between conveyors. For example, in U.S. patent application Ser. No. 11/521,576, filed Sep. 13, 2006, which is hereby incorporated by reference herein in its entirety, describes a system suitable for use with embodiments of the present invention to move substrate carriers 120 from one conveyor to another. In some embodiments, a single conveyor may be used both internal and for inter-building transfers.

In operation, the stockers 122 may unload substrate carriers 120 from the internal conveyors 124, 126, 128 and the unloaded substrate carriers 120 may be transferred to a co-located stocker 122 that is adjacent one of the inter-building conveyors 116, 118. The stocker 122 receiving the substrate carriers 120 may then load the substrate carriers 120 on to an inter-building conveyors 116, 118 upon which the substrate carriers 120 are transported to another building.

The stockers 122 may include a speed match module that allows the stocker 122 to load and unload substrate carriers 120 from the conveyors 116, 118, 124, 126, 128, without stopping or slowing the conveyors 116, 118, 124, 126, 128. In some example embodiments, the conveyors 116, 118, 124, 126, 128 may be adapted to transport about 200 substrate carriers per hour. The conveyors 116, 118, 124, 126, 128 may include identification readers adapted to scan identification codes on the substrate carriers 120.

In at least one embodiment, a speed match module may perform on-the-fly transfers of substrate carriers moving at a substantially constant velocity. In some embodiments, sensors may be employed to detect the position(s) of a vehicle carrying a substrate carrier, detect a speed and/or velocity of a vehicle carrying a substrate carrier and/or detect the presence of a substrate carrier on a vehicle that is transporting the substrate carrier. Robots may grip substrate carriers from a top flange, a bottom or at any suitable location.

As stated previously, in some embodiments, queuing conveyors may be provided at each end of an inter-building conveyor. For example, eight queuing conveyors may be provided at each end of the inter-building conveyor. In some embodiments, there may be four entry and four exit points in each building, each capable of handling 200 substrate carriers/hour. Further, there may be at least as many speed-match modules (8) at both buildings; and each speed-match module may be capable of handling in excess of 200 substrate carriers/hour. In such embodiments, the time to travel between two buildings 200 m apart may be about 400 sec (e.g., at a velocity of 0.5 m/s). Each train may carries eight substrate carriers between buildings, with a pitch between trains of about 10 m (e.g., 20 seconds). For example, every twenty seconds, eight substrate carriers may be transferred. The total number of trains may equal the length/pitch (e.g. about 40).

In some embodiments, building-to-building conveyors may include equispaced cars and/or conveyors that move continuously. Each queuing-type conveyor may include an ID reader, for example, capable of handling 200 substrate carriers per hour. Substrate carriers may be moved to the output port of a conveyor for pickup by a speed-match module for transfer. Speed-match transfer modules may pickup substrate carriers from queuing conveyor output ports and transfer the substrate carriers to the moving conveyor ‘on-the-fly’ without stopping or slowing down.

In some embodiments, the inter-building conveyor may include a multitude of equispaced cars. The conveyor system may be driven by a continuous drive system. For example, the conveyor system may include roller based cars, propelled by a continuous belt (e.g., under tension or non-tension). In some embodiments, the belt does not take any load, but merely propels the conveyor.

In one exemplary embodiment, a move rate of about 1500 substrate carriers/hour may be used. Assuming a substrate carrier transfer may occur every 2.5 seconds, at a conveyor velocity of 0.5 m/s, and a car pitch on the conveyor of 1.25 m, a total of 270 cars may be used. Other move rates, transfer times, conveyor velocities and/or car pitches may be used.

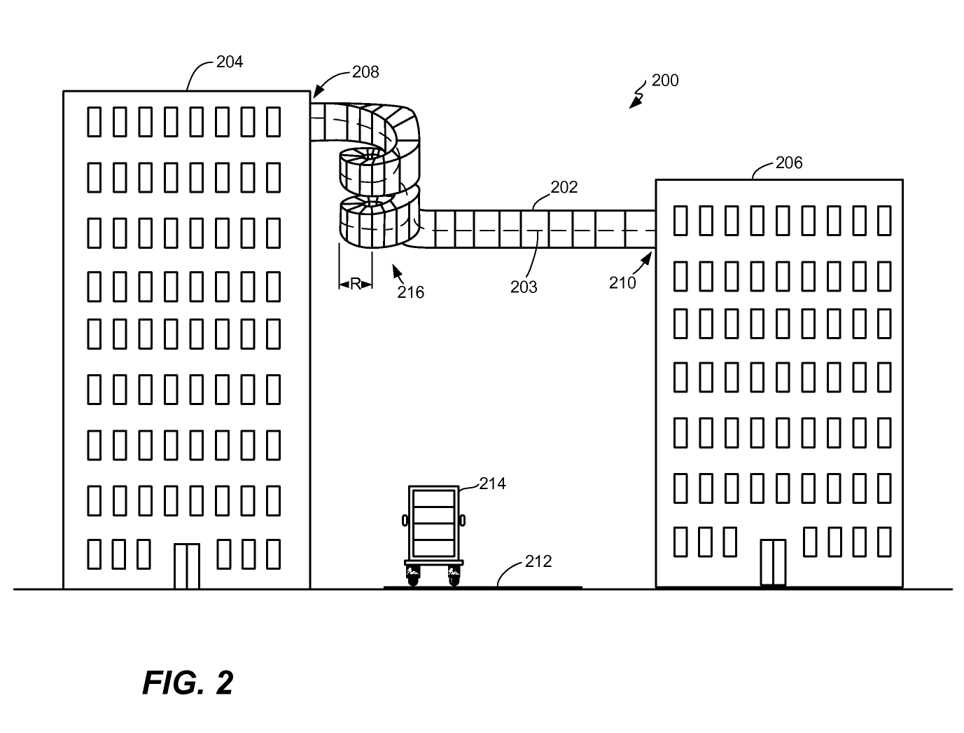

FIG. 2 is a representative side view of a first elevation-changing inter-building transport system 200 provided in accordance with the present invention. With reference to FIG. 2, the transport system 200 includes a housing 202 and internal conveyor 203 (shown in phantom) that extend between a first building 204 and a second building 206 and allow substrate carriers to be transferred between the first and second buildings 204, 206 as described previously with reference to FIG. 1. While only one housing and/or conveyor is shown in FIG. 2, it will be understood that additional housings and/or conveyors may extend between the first and second buildings 204, 206 (e.g., 2, 3, 4, 5, etc.).

In the embodiment of FIG. 2, the conveyor 203 and/or housing 202 may receive substrate carriers from the first building 204 at a first elevation 208 and deliver the substrate carriers to the second building 206 at a second elevation 210 (or vice versa). In some embodiments, the first elevation 208 may be above the second elevation 210 (as shown in FIG. 2), while in other embodiments, the first elevation 208 may be below the second elevation 210. Preferably the first and second elevations 208, 210 are at a sufficient height so that the housing 202 does not create an obstruction to and/or prevent travel beneath the housing 202. For example, in some embodiments, the housing 202 may extend over a roadway 212; and the housing 202 may be at an elevation that allows traffic (e.g., a vehicle 214) to travel underneath the housing 202.

In the embodiment of FIG. 2, the housing 202 and the conveyor 203 include a spiral portion 216 for transporting substrate carriers between the first and second elevations 208, 210. The spiral portion 216 allows substrate carriers to reach a higher (or lower) elevation gradually by moving up (or down) the spiral portion 216. In some embodiments, the design of the conveyor 203 may limit the radius R of the spiral portion 216. For example, if the conveyor 203 employs trains or cars to transport substrate carriers, the radius R of the spiral portion 216 may be limited by the dimensions of the trains or cars (e.g., length, spacing between trains/cars, etc.).

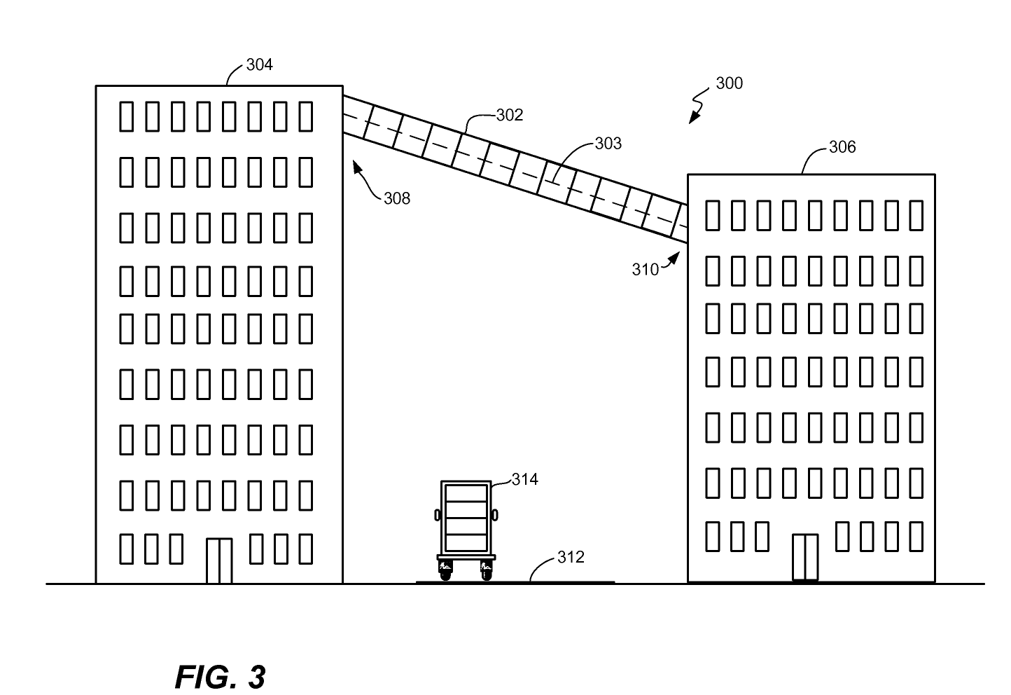

FIG. 3 is a representative side view of a second elevation-changing inter-building transport system 300 provided in accordance with the present invention. With reference to FIG. 3, the transport system 300 includes a housing 302 and an internal conveyor 303 (shown in phantom) that extend between a first building 304 and a second building 306 and allow substrate carriers to be transferred between the first and second buildings 304, 306 as described previously with reference to FIG. 1. While only one housing and/or conveyor is shown in FIG. 3, it will be understood that additional housings and/or conveyors may extend between the first and second buildings 304, 306 (e.g., 2, 3, 4, 5, etc.).

In the embodiment of FIG. 3, the conveyor 303 and/or housing 302 may receive substrate carriers from the first building 304 at a first elevation 308 and deliver the substrate carriers to the second building 306 at a second elevation 310 (or vice versa). In some embodiments, the first elevation 308 may be above the second elevation 310 (as shown in FIG. 3), while in other embodiments, the first elevation 308 may be below the second elevation 310. Preferably the first and second elevations 308, 310 are at a sufficient height so that the housing 302 does not create an obstruction to and/or prevent travel beneath the housing 302. For example, in some embodiments, the housing 302 may extend over a roadway 312; and the housing 302 may be at an elevation that allows traffic (e.g., a vehicle 314) to travel underneath the housing 302.

In the embodiment of FIG. 3, the housing 302 and the conveyor 303 extend between the first and second buildings 304, 306 at an incline. The incline allows substrate carriers to reach a higher (or lower) elevation gradually by moving up (or down) the incline. In some embodiments, the incline may be a constant gradient incline, while in other embodiments, multiple gradients may be used. Any suitable incline angle may be employed.

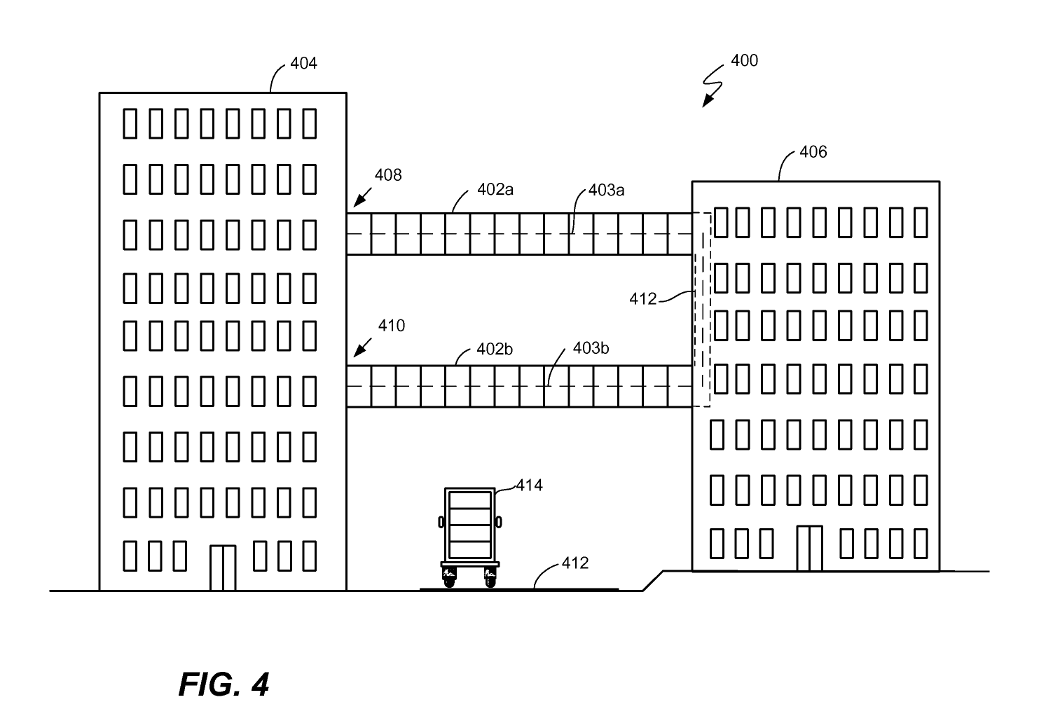

FIG. 4 is a representative side view of a third elevation-changing substrate carrier transport system 400 provided in accordance with the present invention. With reference to FIG. 4, the transport system 400 includes a first housing 402a and a first internal conveyor 403a, and a second housing 402b and a second internal conveyor 403b, that extend between a first building 404 and a second building 406 and allow substrate carriers to be transferred between the first and second buildings 404, 406. While only two housings and/or conveyors are shown in FIG. 4, it will be understood that additional housings and/or conveyors may extend between the first and second buildings 404, 406 (e.g., 3, 4, 5, 6, etc.).

In the embodiment of FIG. 4, the first housing 402a is positioned at a first elevation 408 and the second housing 402b is positioned at a second elevation 410. Further, the transport system 400 includes an elevating mechanism 412 (shown in phantom in the second building 406 in FIG. 4) that allows substrate carriers to be transferred between the first and second elevations 408, 410 and/or between the conveyors 403a-b and/or housings 402a-b. Through use of the elevating mechanism 412, substrate carriers may be transferred from the first building 404 at the first elevation 408 to the second building 406 at the second elevation 410 (or vice versa), or substrate carriers may be transferred from the first building 404 at the second elevation 410 to the second building 406 at the first elevation 408 (or vice versa). The elevating mechanism 412, or a separate elevating mechanism, may be employed within the first building 404 and/or outside of the buildings 404, 406 between the conveyors 403a-b.

The elevating mechanism 412 may include any suitable device for elevating a substrate carrier such as an elevator, lift pins, a substrate handler or the like. Preferably the first and second elevations 408, 410 are at a sufficient height so that the housing 402b does not create an obstruction to and/or prevent travel beneath the housing 402b. For example, in some embodiments, the housings 402a-b may extend over a roadway 414; and the housings 402a-b may at an elevation that allows traffic (e.g., a vehicle 216) to travel underneath the housings 402a-b.

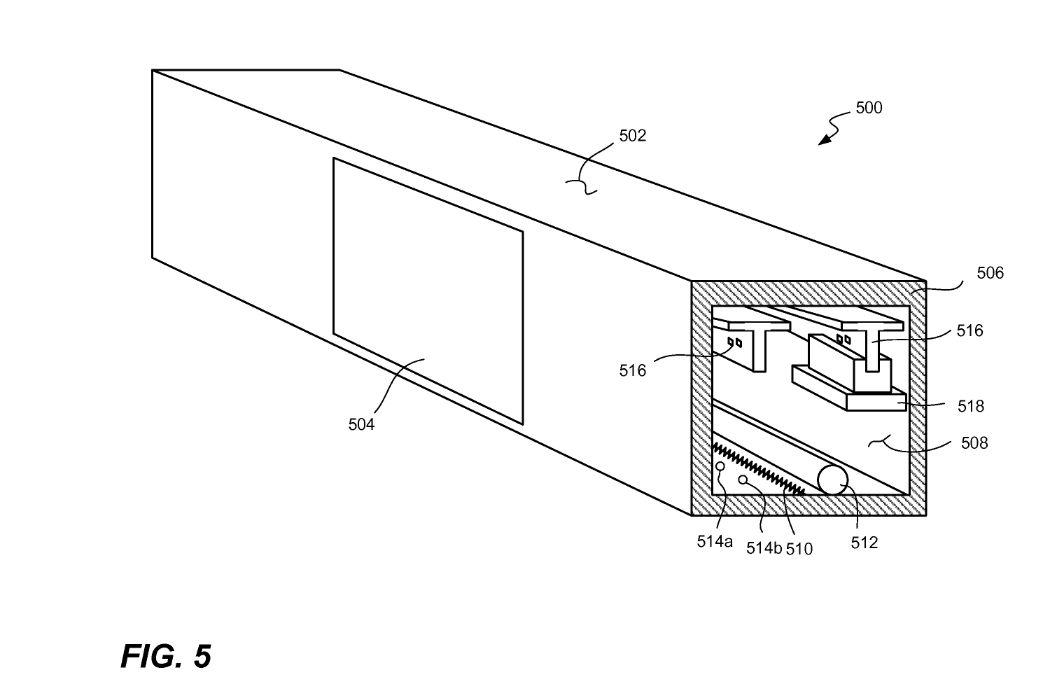

FIG. 5 is an exemplary cross-sectional perspective embodiment of a portion of a housing 500 provided in accordance with the present invention. In some embodiments, the housings 102, 104, 106, 108, 202, 302, 402a and/or 402b may be similar to the housing 500 of FIG. 5, although other housing configurations may be used.

With reference to FIG. 5, the housing 500 includes an outer shell 502 formed from one or more suitable lightweight materials such as aluminum, plastic, stainless steel, etc. The outer shell 502 may include one or more access panels 504 for providing access to the inside of the housing 500 (e.g., for periodic maintenance, to manually remove a substrate carrier, etc.). The outer shell preferably is weatherproof so as to protect any substrate carriers and/or other equipment stored therein. In some embodiments, one or more layers of insulation 506 may be provided near the outer shell 502 to insulate an inner region 508 of the housing 500 from the outside environment that surrounds the housing 500.

In addition insulation 506, other methods of may be employed to control (and/or monitor) the environment within the housing 500. For example, one or more heaters 510 (e.g., resistive, lamp-based, etc., heaters) and gas supply lines and/or ducts 512 (e.g., clean dry air, nitrogen, another inert gas supply lines or ducts, etc.) may be used to control the environment within the housing (e.g., pressure, temperature, gas content, etc.). For example, one or more temperature and/or pressure sensors 514a-b may be employed to monitor temperature and/or pressure within the housing 500, and the heater(s) 510 and/or gas supply line(s) and/or duct(s) may be used to regulate temperature and/or pressure within the housing 500. In some embodiments, a controller may be coupled to the system (e.g., to the sensors, conveyor drive motors, monitoring systems, etc.) to control operation of the inter-building transport system.

As shown in FIG. 5, the housing 500 includes one or more conveyors 516 for transporting substrate carriers 518 within the housing 516. Any suitable conveyors may be used such as horizontally or oriented conveyors. For example, U.S. Pat. No. 7,077,264, which is hereby incorporated by reference herein, describes conveyors systems that employ a ribbon-like structure for transporting substrate carriers and that may be used within the housing 500. In some embodiments, the conveyor 516 continuously moves and/or rotates, without stopping during the loading of substrate carriers onto the conveyor 516 and/or the unloading of substrate carriers from the conveyor 516 as described, for example, in U.S. patent application Ser. No. 10/650,480, filed Aug. 28, 2003 and titled “Substrate Carrier Handler That Unloads Substrate Carriers Directly From a Moving Conveyor” (Attorney Docket No. 7676), which is hereby incorporated by reference herein in its entirety.

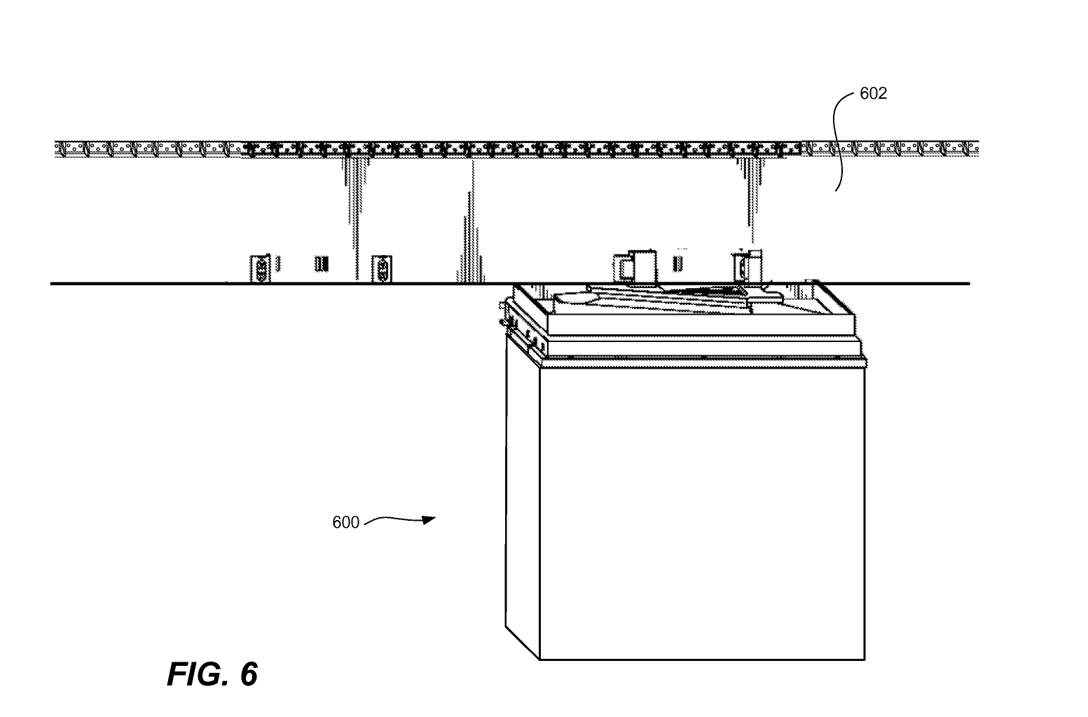

FIG. 6 is a side perspective view of an exemplary multi-carrier transport unit 600 that may be employed to transport multiple substrate carriers (e.g., a batch of substrate carriers) within a housing in accordance with the present invention. For example, the multi-carrier transport unit 600 may include shelves or other support structure (not shown) for supporting two or more substrate carriers during transport by a conveyor 602 through any of the housings described herein. In some embodiments, the multi-carrier transport unit 600 may house two or more small lot substrate carriers, each adapted to hold a maximum of 12 or fewer substrates, and more preferably a maximum of 5 or fewer substrates. Any of stockers or other substrate handling devices described herein may be employed to load substrate carriers into or remove substrate carriers from a multi-carrier transport unit 600 (e.g., a batch carrier substrate carrier).

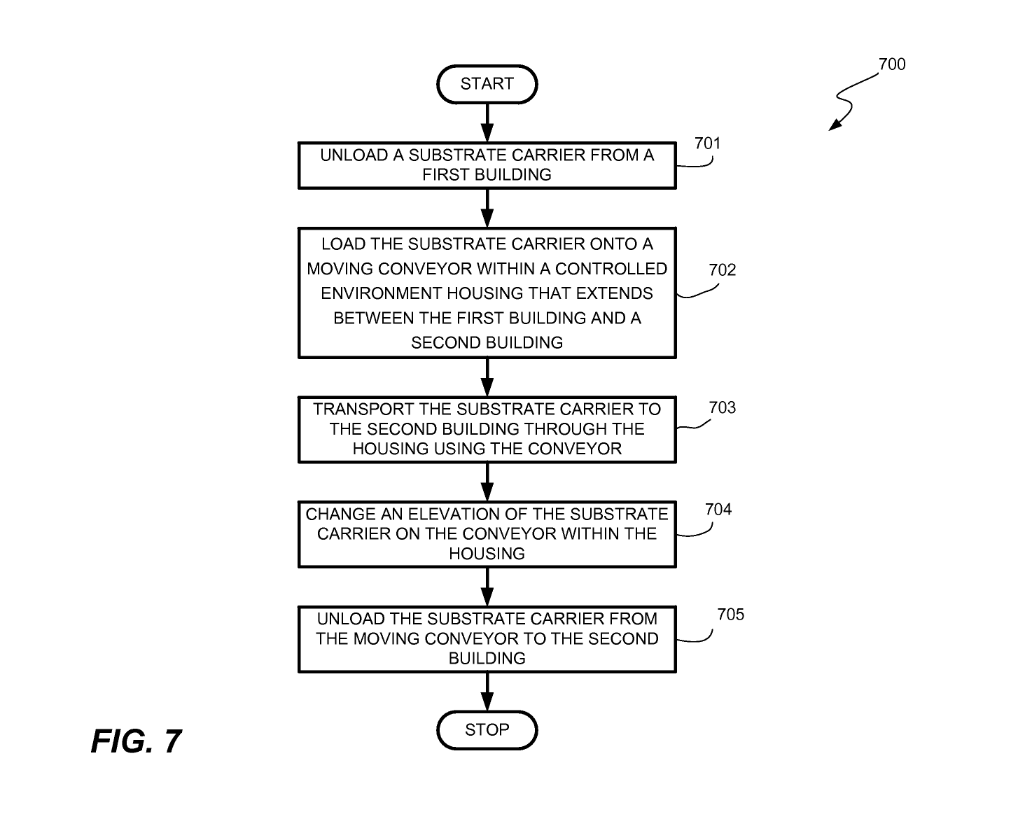

FIG. 7 is a flowchart of an exemplary method 700 provided in accordance with the present invention. The method 700 begins in step 701 in which a substrate carrier is unloaded from a first building, such as from a conveyor in the first building using a stocker or similar device. In step 702, the stocker or another device is employed to load the substrate carrier onto another conveyor within an housing that extends between the first building and a second building. It at least one embodiment, the substrate carrier is loaded onto the conveyor while the conveyor is in motion and/or the housing is environmentally controlled (as previously described).

In step 703, the substrate carrier is transported between the first and second buildings through the housing the conveyor. In optional step 704, the conveyor or an elevating mechanism may be employed to change an elevation of the substrate carrier.

In step 705, the substrate carrier is unloaded from the conveyor into the second building. In some embodiments, the substrate carrier is unloaded from the conveyor while the conveyor is in motion. The method 700 then ends.

The foregoing description discloses only exemplary embodiments of the invention. Modifications of the above disclosed apparatus and methods which fall within the scope of the invention will be readily apparent to those of ordinary skill in the art. Accordingly, while the present invention has been disclosed in connection with exemplary embodiments thereof, it should be understood that other embodiments may fall within the spirit and scope of the invention as defined by the following claims.

The invention claimed is:

1. A substrate carrier transport system comprising:
a housing that extends outside of and between a first building and a second building;
a conveyor positioned within the housing and adapted to:
receive a substrate carrier at the first building; and
transport the substrate carrier to the second building within the housing; and
an environmental control system adapted to at least one of monitor and control an environment within the housing so as to protect the substrate carrier from an environment outside of the housing.

2. The substrate carrier transport system of claim 1 wherein the housing includes at least one maintenance access location that allows access to an interior of the housing from outside of the housing.

3. The substrate carrier transport system of claim 1 wherein the conveyor is adapted to receive substrate carriers from the first building at a first elevation and deliver substrate carriers to the second building at a second elevation.

4. The substrate carrier transport system of claim 3 wherein the conveyor includes an incline for transporting substrate carriers between the first and second elevations.

5. The substrate carrier transport system of claim 3 wherein the conveyor includes a spiral portion for transporting substrate carriers between the first and second elevations.

6. The substrate carrier transport system of claim 1 wherein the conveyor is adapted to move continuously without stopping during loading of substrate carriers onto or unloading of substrate carriers from the conveyor.

7. The substrate carrier transport system of claim 1 wherein the environmental control system is adapted to at least one of monitor and control temperature, pressure and gas content of the housing.

8. The substrate carrier transport system of claim 1 further comprising a loading device positioned near the first building and adapted to load substrate carriers from the first building onto the conveyor.

9. The substrate carrier transport system of claim 8 wherein the loading device is adapted to load substrate carriers from the first building onto the conveyor while the conveyor is in motion.

10. The substrate carrier transport system of claim 9 wherein the loading device is adapted to unload substrate carriers from a moving conveyor within the first building.

11. The substrate carrier transport system of claim 8 wherein the loading device is adapted to load a plurality of substrate carriers into a multi-carrier transport unit and load the multi-carrier transport unit onto the conveyor.

12. The substrate carrier transport system of claim 1 further comprising an unloading device positioned near the second building and adapted to unload substrate carriers from the conveyor to the second building.

13. The substrate carrier transport system of claim 12 wherein the unloading device is adapted to unload substrate carriers from the conveyor to the second building while the conveyor is in motion.

14. The substrate carrier transport system of claim 13 wherein the unloading device is adapted to load substrate carriers onto a moving conveyor within the second building.

15. The substrate carrier transport system of claim 12 wherein the unloading device is adapted to unload a multi-carrier transport unit from the conveyor, the multi-carrier transport unit adapted to hold a plurality of substrate carriers.

16. The substrate carrier transport system of claim 15 wherein the unloading device is adapted to unload substrate carriers from the multi-carrier transport unit.

17. The substrate carrier transport system of claim 1 further comprising a cleaning unit adapted to clean substrate carriers transported within the housing.

18. The substrate carrier transport system of claim 1 wherein the first building includes a first fabrication facility and the second building includes a second fabrication facility.

19. The substrate carrier transport system of claim 1 wherein the first building includes a fabrication facility and the second building includes a substrate carrier warehousing facility.

20. A method of transporting substrate carriers comprising:
unloading a substrate carrier from a first building;
loading the substrate carrier onto a conveyor within a controlled environment housing that extends between the first building and a second building;
transporting the substrate carrier to the second building through the housing the conveyor; and
unloading the substrate carrier from the conveyor to the second building.

21. The method of claim 20 wherein transporting the substrate carrier includes changing an elevation of the substrate carrier.

22. The method of claim 20 wherein loading of the substrate carrier onto the conveyor and unloading of the substrate carrier from the conveyor occur while the conveyor is in motion.

23. A substrate carrier transport system comprising:
a housing that extends outside of and between a first building and a second building; and
a conveyor positioned within the housing and adapted to:
receive a substrate carrier at the first building; and
transport the substrate carrier to the second building within the housing;
wherein the conveyor is adapted to receive substrate carriers from the first building at a first elevation and deliver substrate carriers to the second building at a second elevation.

24. The substrate carrier transport system of claim 23 wherein the housing includes at least one maintenance access location that allows access to an interior of the housing from outside of the housing.

25. The substrate carrier transport system of claim 23 wherein the conveyor includes an incline for transporting substrate carriers between the first and second elevations.

26. The substrate carrier transport system of claim 23 wherein the conveyor includes a spiral portion for transporting substrate carriers between the first and second elevations.

27. The substrate carrier transport system of claim 23 wherein the conveyor is adapted to move continuously without stopping during loading of substrate carriers onto or unloading of substrate carriers from the conveyor.

28. A method of transporting substrate carriers comprising:
unloading a substrate carrier from a first building;
loading the substrate carrier onto a conveyor within a housing that extends between the first building and a second building;
transporting the substrate carrier to the second building through the housing the conveyor; and
unloading the substrate carrier from the conveyor to the second building;
wherein transporting the substrate carrier includes changing an elevation of the substrate carrier.

29. The method of claim 28 wherein loading of the substrate carrier onto the conveyor and unloading of the substrate carrier from the conveyor occur while the conveyor is in motion.
